(19) United States
(12) Patent Application Publication
(10) Pub. No.: US 2003/0127016 A1
(43) Pub. Date: Jul. 10, 2003

(54) Dampening composition for lithographic printing

(76) Inventors: Hiroyuki Kurokawa, Tokyo (JP); Toshiro Kondo, Tokyo (JP)

Correspondence Address: MANELLI DENISON & SELTER, 2000 M STREET NW SUITE 700, WASHINGTON, DC, 20036-3307, US

(21) Appl. No.: 10/253,709

(22) Filed: Sep. 25, 2002

(30) Foreign Application Priority Data
Sep. 28, 2001 (JP) 2001-304386

(51) Int. Cl. G03F 7/06; G03F 7/07; G03F 7/38; B41F 1/18; B41F 7/00; C09K 3/00

(52) U.S. Cl. 106/2; 430/264; 430/303; 430/309; 430/331; 430/204; 101/451

(57) ABSTRACT

There is disclosed a dampening composition for lithographic printing which comprises a (poly) propylene glycol alkyl ether and an ethylene oxide adduct of acetylene glycol.

### BACKGROUND OF THE INVENTION

1. Field of the invention

This invention relates to a dampening composition for lithographic printing, more specifically to a dampening composition to be preferably used in lithographic printing using ink containing soybean oil, further to a dampening composition suitable for printing using a lithographic printing plate which utilizes a light-sensitive silver halide.

2. Prior art

Lithographic printing is a printing system which adroitly utilizes characteristics in which water and oil do not inherently mix to each other. A lithographic printing plate comprises oleophilic image portions which are receptive to oily inks and oil-repellent non-image portions which are not receptive to the inks. In general, said non-image portions are receptive to water, namely, hydrophilic. Usual lithographic printing is carried out by feeding both ink and a dampening solution to the surface of printing plates to allow the image portions to receive preferentially the coloring ink and the non-image portions to receive preferentially the dampening solution and, then, transferring the ink on the image portions onto a substrate such as paper. In such a lithographic printing, it is important that inks and the dampening solutions are fed onto the lithographic plate with a suitable balance. If an amount of the dampening solution to be fed onto the lithographic plate is too little, there is a problem that ink stain occurs at the non-image portions while if an amount of the dampening solution is too much, emulsification of the ink excessively proceeds whereby a density at the image portions becomes insufficient.

In a conventionally known dampening solution, there is a solution in which a hydrophilic agent such as phosphoric acid or a salt thereof, Gum Arabic, carboxymethyl cellulose (CMC) and the like are contained. These dampening solutions containing these compounds, however, involve a problem that they do not uniformly wet at the non-image portions, so that they are insufficient for the characteristics of a dampening solution used for high speed printing in recent years.

To overcome these problems, isopropyl alcohol (IPA) has been added to a dampening solution in an amount of about 10 to 25% by volume. IPA lowers surface tension of the dampening solution, so that wettability at the non-image portions becomes good and an amount of the dampening solution to be fed can be reduced. Thus, emulsification of the inks less occurs and there is a merit in working that adjustment of a balance in feeding amounts of the inks and the dampening solution is easy, so that it has widely been used.

In recent years, an interest in industrial pollution or circumferencial problem is heightened and use of an organic solvent such as IPA tends to be regulated in view of hygienic safety. Thus, it has been proposed to use various kinds of surfactants in place of IPA as disclosed in, for example, Japanese Patent Publications No. 25075/1980 and No. 19757/1980. However, these dampening solutions lower surface tension but are difficult to adjust a balance in feeding amounts of inks and water as compared with the dampening solution using IPA and wettability at the non-image portion was insufficient.

On the other hand, as a compound substituting for IPA, various kinds of organic solvents to lower a surface tension have been disclosed in Japanese Provisional Patent Publications No. 363297/1992, No. 220398/1992 and No. 310092/1990 such as an alcohol (ethyl alcohol, butyl alcohol and the like), a glycol ether (ethylene glycol, triethylene glycol monobutyl ether, propylene glycol monobutyl ether and the like), a polyol (glycerin and the like). Moreover, in Japanese Provisional Patent Publication No. 199693/1982, a dampening solution containing 2-ethyl-1,3-hexanediol and at least one of completely water-soluble propylene glycol, ethylene glycol, dipropylene glycol, hexylene glycol and the like. These dampening compositions do not contain IPA, so that they are advantageous in the point of hygienic safety. However, at the time of high speed printing, wettability at the non-image portions is insufficient, and as a result, a problem arises that scumming or filling-up (a phenomenon where dots are twined) occurs.

Moreover, in Japanese Provisional Patent Publications No. 221179/1993 and No. 132753/1996, a dampening composition containing a compound in which propylene oxide or propylene oxide and ethylene oxide is/are added to a polyvalent alcohol with trivalent or more has been disclosed. This dampening solution certainly does not involve a problem in hygienic safety and a fire but a problem frequently arises that scumming or filling-up occurs at the non-image portions depending on a combination of printing conditions such as a printer, a dampening system, ink, a printing plate and the like. Also, when printing for a long time is carried out, a balance of emulsification of ink is lost due to increase in a temperature of the printer. As a measure therefore, when a feeding amount of the dampening solution is made large, emulsification of ink excessively proceeds depending on the kind of inks whereby a problem occurs that an ink density is lowered.

On the other hand, in recent years, in view of working atmosphere or global atmosphere, an aroma-free ink (AF ink) for lithographic printing using an aroma-free solvent containing no aromatic component has been developed and used in place of a petroleum type solvent which has conventionally been used. In the United States, the American Newspaper Association (NAA) has paid attention to vegetable oil in place of the petroleum type solvent at the time of oil shock occurred at 1970^{th} and soybean oil has been started to be used as a solvent for newspaper inks. Thereafter, during the late of 1980^{th} and the first half of 1990^{th}, the government of the United States or the American Soybean Association (ASA) has positively proceeded to use soybean oil (vegetable oil) for the purpose of environmental protection (prevention of air pollution) or promotion of agriculture.

In Japan, use of soybean oil ink has been promoted accompanying with heightening in a sense of circumferential problem such as change from a society of a large amount of consumption and a large amount of disposal to a society of recycling material, use of soybean oil ink has promoted. Soybean oil inks have been developed and sold in sheetfed ink, web heatset ink, form ink, news ink and the like. In Japanese Provisional Patent Publication No. 293169/1999, printing ink using soybean oil as an aroma-free solvent has been disclosed. Moreover, in Japanese Provisional Patent Publications No. 2000-143785 and No. 2000-159868, printing inks using soybean oil have been disclosed.

However, the soybean oil ink also involves various problems. In sheetfed ink, delay in drying of the ink is a great problem. In the conventional off-set sheetfed ink and web ink, linseed oil or tung oil has generally been used as dry oil (vegetable oil). Ink shall form “a film” when it is printed on a paper by drying, and a resin or dry oil in the ink is reacted with oxygen (oxidation polymerization) in air to form a cured material. The soybean oil is called to be “semi-dry oil” as compared with the linseed oil or tung oil among the vegetable oils, and a saturation degree of aliphatic acid constituting it is high (an iodine value is low). Thus, when the soybean oil is used in ink, an oxidation polymerization property thereof is low and drying becomes slow. Also, color ink used in color printing employs a relatively hydrophilic pigment in many cases, which pigment promotes emulsification whereby drying becomes too slow. When drying is slow, a setting property of ink on a paper is bad. In a sheeting printer, printed papers are laminated one after another, so that if a setting property on a paper is bad, a problem of causing a so-called back transfer, in which ink transfers to a back surface of the next paper, arises. This remarkably occurs when an art paper or a coated paper is used and becomes a serious problem.

In printing using such an easily emulsifiable soybean oil ink, when printing is carried out by using a dampening solution using a surfactant or an organic solvent in place of IPA, a balance of feeding ink and the dampening solution can be difficultly adjusted, which further promotes emulsification. As a result, a problem occurred that drying becomes slower and a problem also occurred that transferability of ink to the image portion becomes bad whereby a density of the printed material is lowered.

Also, in lithographic printing using soybean oil ink, various problems increased by changing printing conditions (for example, a kind of the printing plate or a dampening solution, or change in a kind of dampening system). For example, when printing is carried out by using a printer having a continuous dampening system with a silver salt printing paper (a lithographic printing plate utilizing a light-sensitive silver halide) having lower water-retention property as compared to that of a PS plate, there is a tendency of increasing a degree of scumming in the soybean oil ink whereas scumming tends to be likely caused in the conventional ink. Accordingly, in lithographic printing using the soybean oil ink, it has been desired to provide a dampening composition or a printing method which is not affected by printing conditions such as a printing plate, a dampening solution, a dampening system, and the like, and can carry out proper printing.

On the other hand, in a lithographic printing plate using an aluminum plate as a support, in general, a surface thereof is roughened and further subjected to anodizing treatment to improve hydrophilicity on the surface of the aluminum plate. This roughened and anodized aluminum surface show high hydrophilicity, but is chemically unstable. Particularly under high temperature and high humidity conditions, the hydrophilicity can be easily lost and it becomes a cause of ink stain at the non-image portions. On the other hand, in an actual site of printing, interruption of printing occurs as usual working due to change of paper, paper jamming, or a rest taken by a worker. In such a case, a printing plate mounted on a printer is exposed to high temperature and high humidity conditions. Thus, there are specific problems of a lithographic printing plate using aluminum as a support that an aluminum surface is corroded to cause ink stain, and dot like ink stain which is so-called oxidation occurs when the aluminum surface is exposed to air for a long period of time.

### SUMMARY OF THE INVENTION

An object of the present invention is to provide a dampening composition for lithographic printing which is safe in working atmosphere, causes neither scumming nor filling-up under any printing conditions and gives good printed products without lowering in density of the printed products even when printing is carried out for a long period of time. Another object of the present invention is to provide a printing method which does not lower a density of a printed product without excessively promote emulsification in printing using ink containing soybean oil. A further object of the present invention is to provide a dampening composition and a printing method suitable for printing using a lithographic printing plate which utilizes light-sensitive silver halide. A still further object of the present invention is to provide a dampening composition which can prevent from causing oxidation which is a specific problem in a lithographic printing plate using an aluminum plate as a support.

The above objects of the present invention can be basically accomplished by a dampening composition which comprises a (poly)propyleneglycol alkyl ether and an ethylene oxide adduct of acetylene glycol.

One of the preferred embodiments of the present invention is a dampening composition further containing inorganic fine particles having an average particle size of 0.1 μm or less.

Another preferred embodiment of the present invention is a dampening composition further containing a pH buffer having a pH of 4 to 7 in an amount of 0.01 mol/liter or more.

Still further preferred embodiment of the present invention is a dampening composition further containing phosphoric acid and at least one of organic phosphonic acid compounds.

Also, the dampening composition of the present invention can be suitably used when printing is carried out by using ink containing soybean oil.

Also, the dampening composition of the present invention can be suitably used when printing is carried out for a lithographic printing plate using a light-sensitive silver halide as a lithographic printing plate.

### DESCRIPTION OF THE PREFERRED EMBODIMENTS

In the following, the present invention is explained in more detail.

The (poly) propylene glycol alkyl ether to be used in the present invention means to include propylene glycol alkyl ether and polypropylene glycol alkyl ether, preferably having 1 to 5 recurring units of the propyleneoxy group, more preferably 1 to 3 recurring units. An alkyl group of the (poly)propylene glycol alkyl ether preferably has 1 to 5 carbon atoms, more preferably 3or 4carbon atoms. More preferred compound thereof is monoalkyl ether of (poly)propylene glycol. The (poly)propylene glycol alkyl ether to be used in the present invention is represented by the formula (1) mentioned below.

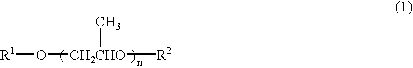

wherein R¹ and R² each represent a hydrogen atom or an alkyl group, either one of R¹ and R² represents an alkyl group and n is an integer of 1 to 5.

In the formula (I), R¹ is preferably an alkyl group having 1 to 5 carbon atoms, more preferably an alkyl group having 3 or 4 carbon atoms, R² is preferably a hydrogen atom and n is an integer preferably 1 to 5, more preferably 1 to 3.

As the alkyl group represented by R¹, there may be mentioned a propyl group such as an n-propyl group and an isopropyl group, or a butyl group such as an n-butyl group, an isobutyl group and a tert-butyl group.

As the (poly)propylene glycol alkyl ether preferably used in the present invention, there may be mentioned, for example, propylene glycol mono-n-butyl ether, dipropylene glycol mono-n-butyl ether, tripropylene glycol mono-n-butyl ether, propylene glycol monoisobutyl ether, dipropylene glycol monoisobutyl ether, tripropylene glycol monoisobutyl ether, propylene glycol mono-tert-butyl ether, dipropylene glycol mono-tert-butyl ether, tripropylene glycol mono-tert-butyl ether, propylene glycol mono-n-propyl ether, dipropylene glycol mono-n-propyl ether, tripropylene glycol mono-n-propyl ether, propylene glycol monoisopropyl ether, dipropylene glycol monoisopropyl ether, tripropylene glycol monoisopropyl ether, and the like. These compounds may be used singly or in combination of two or more.

The dampening solution is generally fed as a condensed solution and diluted to about 30-fold to about 200-fold at the time of use. This dilution ratio is generally set previously by the supplier of the dampening solution. In the present invention, this diluted solution is called to as working solution. In the following, an amount to be added of the respective components is a concentration in the working solution.

An amount of the above-mentioned (poly)propylene glycol alkyl ether to be added to the dampening composition (working solution) is preferably 0.015 to 3% by weight, more preferably 0.015 to 2% by weight.

An ethylene oxide adduct of acetylene glycol to be used in the present invention is represented by the formula (2) mentioned below.

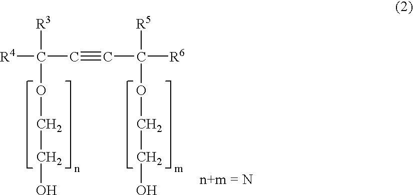

wherein R³, R⁴, R⁵ and R⁶ each represent an alkyl group, and n+m=N means a molar number of added ethylene oxide in the range of 2 to 30.

In the formula (2), the alkyl group of R³, R⁴, R⁵ and R⁶ is preferably an alkyl group having 1 to 4 carbon atoms, and R³ and R⁵ are particularly preferably methyl groups. The number of added mols of the above-mentioned ethylene oxide unit is preferably 2 or more, more preferably 3 or more, and the upper limit thereof 30 or so, and preferably 10 or less. In the following, preferred formula (3) is shown.

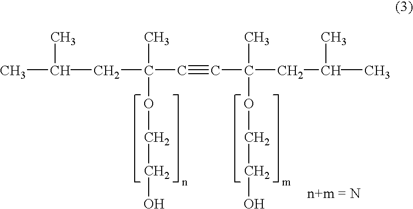

wherein n+m=N means a molar number of added ethylene oxide and preferably in the range of 2 to 30. An amount of the compound mentioned above is preferably 0.005 to 3% by weight, more preferably 0.01 to 1% by weight, most preferably 0.05 to 1% by weight based on the total amount of the dampening composition (working solution). An ethylene oxide adduct of acetylene glycol is produced by AIR PRODUCTS AND CHEMICALS CO., U.S.A., and commercially available from NISSIN CHEMICAL INDUSTRIES, INC., Japan under the trade names of Surfynol or Olfin. There may be specifically mentioned, for example, Surfynol 440 (a molar number of ethylene oxide added is 3.5), Surfynol 465 (the same is 10), Surfynol 485 (the same is 30), and the like.

In the dampening composition of the present invention, propylene glycol is preferably used in combination with the above-mentioned (poly)propylene glycol alkyl ether. In particular, when the alkyl group of the (poly)propylene glycol alkyl ether is a propyl group or a butyl group, propylene glycol is preferably used in combination with the same to aid solubility or stability in the dampening solution. An amount of the propylene glycol is preferably 1 to 6-fold in weight, more preferably 2 to 6-fold based on the amount of the (poly)propylene glycol alkyl ether.

To the dampening composition of the present invention, inorganic fine particles having an average particle size of 0.1 μm or less is preferably added. As the inorganic fine particles, there may be mentioned, for example, colloidal silica, colloidal alumina and the like. An amount of the inorganic fine particles in the dampening solution (working solution) is preferably 0.03 to 0.3% by weight, more preferably 0.05 to 0.2% by weight. By adding the inorganic fine particles to the dampening solution, scumming or filling-up (a phenomenon where dots are twined) can be prevented.

To the dampening composition of the present invention, a pH buffer having a pH of 4 to 7 is preferably added in an amount of 0.01 mol or more per liter of the dampening solution (working solution). More preferably, it is in the range of 0.015 to 0.04 mol. By adding the pH buffer, ink can be maintained at a suitably emulsified state. When the suitably emulsified state of ink is not maintained and ink is excessively emulsified, an ink concentration is lowered, while in the reverse state, it becomes a cause of stain at a non-image portion.

The pH buffer to be used in the present invention is a water-soluble organic acid, inorganic acid or a salt thereof. As the organic acid, there may be mentioned, for example, citric acid, succinic acid, glutamic acid, ascorbic acid, acetic acid, lactic acid, tartaric acid, malic acid, malonic acid, benzoic acid, and the like. As the inorganic acid, there may be mentioned, for example, phosphoric acid, nitric acid, sulfuric acid, and the like. Moreover, an alkali metal salt, an alkaline earth metal salt or an ammonium salt of these organic acids or inorganic acids can be used. These pH buffers maybe used singly or in combination of two or more. It is preferably an organic acid.

To the dampening composition of the present invention, at least one of organic phosphonic acid compounds and phosphoric acid are preferably further added. By adding the organic phosphonic acid compound and phosphoric acid to the dampening composition, dot like ink stain which is so-called “oxidation” which is a specific problem in an aluminum lithographic printing plate can be prevented.

The organic phosphonic acid compound to be used in the present invention may include, for example, aminotrimethylene phosphonic acid salt, 1-hydroxyethylidene-1-diphosphonic acid salt, ethylenediaminetetramethylene phosphonic acid salt, diethylenetriaminepentamethylene phosphonic acid salt, hexamethylenediaminetetramethylene phosphonic acid salt, N-carboxymethyl-N,N-dimethylene phosphonic acid salt, N,N-dicarboxymethyl-N-methylene phosphonic acid salt, 2-phosphonobutane-1,2,4-tricarboxylic acid salt and the like, but the present invention is not limited by these. Also, these compounds are already commercially available from respective manufacturers, and can be easily available from, for example, Solutia Japan Co., Ltd. under the registered trade name of “DEQUEST” or Sakai Chemical Industry Co., Ltd. under the registered trade name of “DONSAM”.

These organic phosphonic acid compounds may be used singly or in combination of two or more thereof, and an amount thereof is preferably 0.01 to 1.0 mol per liter of the dampening solution (working solution), more preferably 0.05 to 0.3 mol.

An amount of the phosphoric acid to be used in the present invention is preferably 0.05 to 1% by weight based on the amount of the dampening solution (working solution), more preferably 0.05 to 0.5% by weight.

To the dampening composition of the present invention, in addition to the above-mentioned compounds, respective components such as a pH buffer, a water-soluble polymer, a surfactant, a solubilizing agent, an antiseptic agent, a rust preventive agent, a chelating compound, a defoaming agent, a colorant, a corrosion resistant agent, and the like may be added depending on necessity. The pH buffer may include citric acid, acetic acid, tartaric acid, nitric acid, phosphoric acid, etc., and a metal salt thereof. The water-soluble polymer may include Gum Arabic, carboxymethyl cellulose, dextrin, sodium alginate, etc. The surfactant may include an anionic, cationic, nonionic or amphoteric surfactant, and a fluorine type surfactant. The solubilizing agent may include ethylene glycol, hexylene glycol, glycerin, diethylene glycol monomethyl ether, ethylene glycol mono(n-butyl) ether, diethylene glycol isobutyl ether, propylene glycol monopropyl ether, etc. The antiseptic agent may include formalin, a benzotriazole derivative, a 4-iso-thiazolin-3-one compound, etc.

The rust preventive agent may include benzotriazole, thiosalicylic acid, etc., the chelating agent may include ethylenediamine tetraacetic acid, its potassium salt or sodium salt, 1-hydroxyethane-1,1-diphosphonic acid and its potassium salt or sodium salt, etc., the defoaming agent may include a silicone type defoaming agent, etc., and the corrosion resistant agent may include magnesium nitrate, calcium nitrate, etc.

The dampening composition of the present invention has particularly excellent printing characteristics when it is applied to ink containing a soybean oil component. As described above, the ink containing a soybean oil component has been used in place of ink containing a petroleum type solvent or linseed oil in view of working atmosphere or global atmosphere. However, due to the characteristics possessed by the soybean oil, there are problems that drying property of printed ink becomes worse or over-emulsification likely occurs since it is difficult to adjust feeding rate of the ink and the dampening solution. Accordingly, one of the objects of the present invention is to provide a printing method using ink containing a soybean oil component and the dampening composition of the present invention.

When printing is carried out by using the ink containing a soybean oil component in combination with the dampening composition of the present invention, emulsification of the ink is not excessively accelerated, so that transfer of the ink to the image portions do not lower whereby good printed product can be obtained.

Next, a printing method using ink containing a soybean oil component (hereinafter referred to as “soybean oil ink”) according to the present invention will be described. The printing method uses the soybean oil ink and the dampening composition of the present invention.

The soybean oil ink in accordance with the present invention generally comprises a mixture of an organic and/or inorganic pigment, a binder resin, soybean oil, and a petroleum type solvent having a high boiling point, and it may further comprise a plasticizer, a stabilizer, a dryer, a thickening agent, a dispersant, a filler and the like as an additive.

An amount of the soybean oil to be used in the soybean oil ink in accordance with the present invention may vary depending on a kind of the ink. It is contained in an amount of 20% by weight or more in sheetfed ink or form ink, 7% by weight or more in a web heatset ink, 40% by weight or more in black ink and 30% by weight or more in color ink of news ink. These contents of the soybean oil are soybean oil-containing inks regulated by the above-mentioned “ASA”, which can stick a SOY-LOGO SEAL, and they are called to as soybean oil ink as a general term.

As the organic and/or inorganic pigment, disazo yellow, Brilliant Carmine 6B, phthalocyanine Blue, Lake Red C, carbon black, titanium oxide, calcium carbonate, and the like may be used.

As the binder resin, a natural or processed resin such as rosin, copal, dammar, shellac, hardened rosin, rosin ester and the like; a phenol resin, rosin-modified phenol resin, 100% phenol resin, maleic acid resin, alkyd resin, petroleum resin, vinyl resin, acrylic resin, polyamide resin, epoxy resin, aminoalkyd resin, polyurethane resin, aminoplast resin and the like are preferably used.

As the petroleum type solvent having a high boiling point, there may be mentioned a commercially available petroleum type hydrocarbon solvent including normal paraffin or isoparaffin single composition, a compound of paraffin and naphthene, a compound of paraffin, naphthene and aroma, and the like. As the commercially available products, there may be mentioned “ISOLAN S”, “ISOLAN R”, “No. 5 solvent”, “No. 6 solvent”, “No. 7 solvent”, “AF solvent 5”, “AF solvent 6”, “AF solvent 7” all available from Nippon Petrochemicals Co., Ltd., and the like.

With regard to these components, 7 to 40% by weight of soybean oil, 5 to 30% by weight of the binder resin, 5 to 30% by weight of the organic and/or inorganic pigment and 1 to 60% by weight of the petroleum type solvent having a high boiling point are mixed to prepare lithographic printing ink. The soybean oil ink in accordance with the present invention is commercially available from the respective ink manufacturers and can be easily obtained.

Any of the lithographic printing ink containing the soybean oil component in accordance with the present invention can be applied to the present invention irrespective of the kinds thereof so long as it is a lithographic printing plate in which offset printing is carried out by using a dampening solution.

The dampening composition of the present invention is suitable for a method of printing using a lithographic printing plate which utilizes a light-sensitive silver halide. As the representative lithographic printing plate mentioned above, lithographic printing plates made by utilizing silver complex diffusion transfer process may be mentioned. This lithographic printing plate is a lithographic printing plate having at least a physical development nuclei layer and a silver halide emulsion layer on a support, and there are two types. One of which is a lithographic printing plate comprising a subbing layer which also has a function of a halation preventive layer, a silver halide emulsion layer and a physical development nuclei layer in this order on a support comprising a plastic resin film such as polyethylene terephthalate or polyethylene naphthalate, or a polyethylene resin coated paper. They are disclosed, for example, in U.S. Pat. Nos. 3,728,114, 4,134,769, 4,160,670, 4,336,321, 4,501,811, 4,510,228 and 4,621,041, Japanese Patent Publications No. 296143/1987, No. 226658/1988, No. 249852/1988 and No. 261643/1989, Japanese Provisional Patent Publication No. 100430/1993 and the like. As the above-mentioned lithographic printing plates, SILVER DIGI PLATE SDP Series available from Mitsubishi Paper Mills Ltd., or SET PRINT PLUS available from Agfa-Gevaert, Ltd. have been commercially sold.

Another type is a lithographic printing plate comprising a physical development nuclei layer on a roughened and anodized aluminum support, and at least a silver halide emulsion layer thereon. They are disclosed, for example, in U.S. Pat. Nos. 4,567,131, 5,427,889, 6,174,643 and 6,187,503, Japanese Provisional Patent Publications No. 265216/1993, No. 313206/1993, No. 56345/1995, No. 56347/1995, No. 6005/1997 and No. 2000-275855 and the like. As the above-mentioned lithographic printing plates, SILVER DIGI PLATE SDP-α Series available from Mitsubishi Paper Mills Ltd., or Lithostar Series available from Agfa-Gevaert Ltd. have been commercially sold.

### EXAMPLES

In the following, the present invention will be explained by referring to Examples, but the invention is not limited by these as a matter of course.

### Example 1

Dampening compositions having compositions shown in Table 1 were prepared. In the table, a unit is gram. For carrying out the printing, these dampening compositions were used by diluting to 50-fold with water.

TABLE 1
<Test method>

| | Present invention | | | | Comparative | | | |
|---|---|---|---|---|---|---|---|---|
| | 1 | 2 | 3 | 4 | 1 | 2 | 3 | 4 |
| Citric acid | 10 | 10 | 20 | 20 | 10 | 10 | 10 | 20 |
| Trisodium | 15 | 15 | 50 | 50 | 15 | 15 | 15 | 50 |
| citrate | | | | | | | | |
| Phosphoric | 3 | 3 | 3 | 3 | 3 | 3 | 3 | 3 |
| acid | | | | | | | | |
| Carboxymethyl | 4 | 4 | 4 | 4 | 4 | 4 | 4 | 4 |
| cellulose | | | | | | | | |
| Calcium nitrate | 10 | 10 | 10 | 10 | 10 | 10 | 10 | 10 |
| Ethylene glycol | 50 | 50 | 50 | 50 | 50 | 50 | 50 | 50 |
| monoisobutyl | | | | | | | | |
| ether | | | | | | | | |
| Propylene | 200 | 200 | 200 | 200 | 200 | 200 | 200 | 200 |
| glycol | | | | | | | | |
| Dipropylene | 50 | — | 50 | — | — | 50 | — | — |
| glycol | | | | | | | | |
| monobutyl | | | | | | | | |
| ether | | | | | | | | |
| Propylene | — | 50 | — | 50 | — | — | — | — |
| glycol | | | | | | | | |
| monoisobutyl | | | | | | | | |
| ether | | | | | | | | |
| Compound of | 5 | 5 | 5 | 5 | — | — | 5 | — |
| Formula (3) | | | | | | | | |
| (n + m = 3.5) | | | | | | | | |

Made up to 1000 ml with addition of pure water.

As a lithographic printing plate, a lithographic printing plate (SILVER DIGI PLATE SDP-FR175 available from Mitsubishi Paper Mills Ltd.) utilizing silver complex diffusion transfer process and having a subbing layer, a silver halide emulsion layer and a physical development nuclei layer in this order on a polyethylene terephthalate resin film support was used. After the lithographic printing plate was exposed, a printing plate was prepared by using Plate Setter with processer (SDPEco1630, trade name), a developing solution (SLM-EAC, trade name) and a stabilizing solution (SLM-EST, trade name) all available from Mitsubishi Paper Mills Ltd.

Printing was carried out by using a printing machine: RYOBI 560 (manufactured by RYOBI CO., attached with DAHLEGREN dampening system), ink: SUPERTEKPLUS PROCESS MAGENTA M type (available from T&K TOKA CO., LTD.) and the above-mentioned dampening solution.

Evaluation of the printing property: It was evaluated by a number of printed sheets when image density of a printed material is lowered wherein emulsification cannot suitably be maintained, and represented by the following grades. The results of evaluation are shown in Table 2.

S: 15,000 sheets or more

A: 10,000 sheets to less than 15,000 sheets

B: 5,000 sheets to less than 10,000 sheets

C: 2,000 sheets to less than 5,000 sheets

D: less than 2,000 sheets

TABLE 2

| Dampening | Printing | Dampening | Printing |
|---|---|---|---|
| solution | property | solution | property |
| Present | A | Comparative | C |
| invention 1 | | 1 | |
| Present | A | Comparative | C |
| invention 2 | | 2 | |
| Present | S | Comparative | C |
| invention 3 | | 3 | |
| Present | S | Comparative | C |
| invention 4 | | 4 | |

From the above results, in the dampening solutions of the present invention containing (poly)propylene glycol alkyl ether and an ethylene oxide adduct of acetylene glycol, a degree of emulsification of inks can be maintained suitably as compared with those of Comparative samples and good printed products can be obtained. Moreover, in the present inventions 3 and 4 which contain large amount of a pH buffer, printing property is further improved.

### Example 2

Dampening compositions having compositions shown in Table 3 were prepared. In the table, a unit is gram. For carrying out the printing, these dampening compositions were used by diluting to 50-fold with water.

TABLE 3

Present invention

| | 5 | 6 |
|---|---|---|
| Citric acid | 10 | 10 |
| Trisodium citrate | 15 | 15 |
| Phosphoric acid | 3 | 3 |
| Carboxymethyl | 4 | 4 |
| cellulose | | |
| Calcium nitrate | 10 | 10 |
| Ethylene glycol | 50 | 50 |
| monoisobutyl ether | | |
| Propylene glycol | 200 | 200 |
| Propylene glycol | 50 | 50 |
| isobutyl ether | | |
| Compound of Formula | 5 | 5 |
| (3) (n + m = 3.5) | | |
| Colloidal silica | — | 50 |

Made up to 1000 ml with addition of pure water.

<Test Method>

Printing was carried out in the same manner as in Example 1 except for using the dampening solution to those compositions shown in Table 3 and changing the ink to New Champion F gloss violet S Type (available from DAINIPPON INK & CHEMICALS Inc.).

Evaluation of printing property: It was evaluated by a number of printed sheets when scumming or filling-up occurred to fail giving good printed product, and represented by the following grades. The results of evaluation are shown in Table 4.

| | |
|---|---|
| 10,000 sheets or more: | A |
| 5,000 sheets to less than 10,000 sheets: | B |
| 2,000 sheets to less than 5,000 sheets: | C |
| less than 2,000 sheets: | D |

TABLE 4

| Dampening | Printing |
|---|---|
| solution | property |
| Present | B |
| invention 5 | |
| Present | A |
| invention 6 | |

From the above results, it can be understood that occurrence of scumming or filling-up can be prevented by adding inorganic fine particles (colloidal silica) having an average particle diameter of 0.1 μm or less to the dampening composition of the present invention.

### Example 3

Dampening compositions having compositions shown in Table 5 were prepared. In the table, a unit is gram. For carrying out the printing, these dampening compositions were used by diluting to 50-fold with water.

TABLE 5

| | Present invention | | Comparative |
|---|---|---|---|
| | 7 | 8 | 5 |
| Citric acid | 10 | 10 | 10 |
| Trisodium citrate | 15 | 15 | 15 |
| Phosphoric acid | 50 | 50 | 3 |
| Carboxymethyl cellulose | 4 | 4 | 4 |
| Calcium nitrate | 10 | 10 | 10 |
| Ethylene glycol | 50 | 50 | 50 |
| monoisobutyl ether | | | |
| Propylene glycol | 200 | 200 | 200 |
| Dipropylene glycol | 50 | — | — |
| monobutyl ether | | | |
| Propylene glycol | — | 50 | — |
| isobutyl ether | | | |
| Compound of Formula (3) | 5 | 5 | — |
| (n + m = 3.5) | | | |
| Pentasodium aminotri- | 60 | — | — |
| methylene phosphonate | | | |
| Heptasodium diethylene- | — | 60 | — |
| triaminepentamethylene | | | |
| phosphonate | | | |

Made up to 1000 ml with addition of pure water.

<Test Method>

As a lithographic printing plate, a lithographic printing plate (SILVER DIGI PLATE SDP-αRII available from Mitsubishi Paper Mills Ltd.) having a physical development nuclei layer and a silver halide emulsion layer in this order on a surface-roughened and anodized aluminum support was used. Onto the lithographic printing plate was scanning exposed a digital image by an image setter (SDP-α2400; mounting a red laser diode) manufactured by Mitsubishi Paper Mills Ltd., and subjected to developing treatment to prepare a printing plate. A processor used in the developing treatment was SDP-αEcoRf (trade name), a developing solution was SDP-αEDV (trade name), a washing solution was SDP-AST (trade name) and a finishing solution was SDP-αGUM (trade name) all available from Mitsubishi Paper Mills Ltd.

Printing was carried out by using a printing machine: RYOBI 560 (manufactured by RYOBI CO., attached with DAHLEGREN continuous dampening system), ink: New Champion F gloss black H type (available from DAINIPPON INK & CHEMICALS Inc.) and the above-mentioned dampening solution.

Firstly 500 sheets were printed, and then, the printer was allowed to stand for one hour, and printing was started again. When the printing was restarted, whether spot-like ink stain called to as oxidation occurs or not was observed. The results are shown in Table 6.

TABLE 6

| | Presence or absence |
|---|---|
| | of occurrence of |
| Dampening solution | oxidation |
| Present invention 7 | None |
| Present invention 8 | None |
| Comparative 5 | Present |

From the above results, it can be understood that occurrence of oxidation can be prevented by adding an organic phosphonic acid and phosphoric acid to the dampening composition of the present invention.

### Example 4

By using the dampening composition used in Examples 1 and 2, the following test was carried out.

<Test Method>

Test was carried out in the same manner as in Example 1 except for changing the ink used in Example 1 with a soybean oil ink (New Chanpion Naturalith Magenta M type, trade name, available from DAINIPPON INK & CHEMICALS Inc.). The results are shown in Table 7.

TABLE 7

| Dampening | Printing | Dampening | Printing |
|---|---|---|---|
| solution | property | solution | property |
| Present | A | Comparative | D |
| invention 1 | | 1 | |
| Present | A | Comparative | D |
| invention 2 | | 2 | |
| Present | S | Comparative | D |
| invention 3 | | 3 | |
| Present | S | Comparative | D |
| invention 4 | | 4 | |
| Present | A | | |
| invention 5 | | | |
| Present | A | | |
| invention 6 | | | |

From the above results, when printing is carried out by using soybean oil ink, it can be understood that the dampening compositions of the present invention give good printed products with a number of sheets without progressing emulsification of the ink excessively and lowering transferability of the ink to the image portions.

1. A dampening composition for lithographic printing which comprises a (poly) propylene glycol alkyl ether and an ethylene oxide adduct of acetylene glycol.

2. The dampening composition for lithographic printing according to claim 1, wherein the (poly) propylene glycol alkyl ether is a (poly)propylene glycol monoalkyl ether.

3. The dampening composition for lithographic printing according to claim 1, wherein the (poly) propylene glycol alkyl ether is represented by the formula (1): 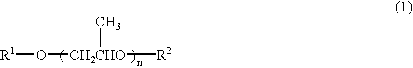
wherein R¹ and R² each represent a hydrogen atom or an alkyl group, either one of R¹ and R² represents an alkyl group and n is an integer of 1 to 5.

4. The dampening composition for lithographic printing according to claim 3, wherein R¹ is an alkyl group having 3 or 4 carbon atoms, R² is a hydrogen atom and n is an integer of 1 to 3.

5. The dampening composition for lithographic printing according to claim 1, wherein the (poly)propylene glycol alkyl ether is propylene glycol monobutyl ether, dipropylene glycol monobutyl ether, tripropylene glycol monobutyl ether, propylene glycol monopropyl ether, dipropylene glycol monopropyl ether or tripropylene glycol monopropyl ether.

6. The dampening composition for lithographic printing according to claim 1, wherein the ethylene oxide adduct of acetylene glycol is represented by the formula (2): 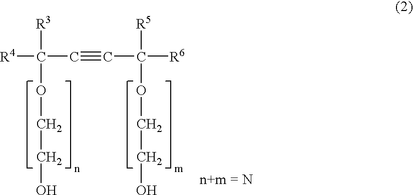
wherein R³ R⁴, R⁵ and R⁶ each represent an alkyl group, and n+m=N means a molar number of added ethylene oxide in a range of 2 to 30.

7. The dampening composition for lithographic printing according to claim 6, wherein R³, R⁴, R⁵ and R⁶ each represent an alkyl group having 1 to 4 carbon atoms, N is 3 or more.

8. The dampening composition for lithographic printing according to claim 1, wherein the ethylene oxide adduct of acetylene glycol is represented by the formula (3): 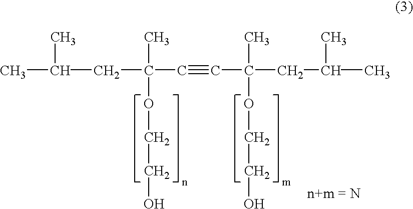
wherein n+m=N means a molar number of added ethylene oxide in a range of 2 to 30.

9. The dampening composition for lithographic printing according to claim 1, wherein the composition further comprises inorganic fine particles having an average particle size of 0.1 μm or less.

10. The dampening composition for lithographic printing according to claim 1, wherein the composition further comprises a pH buffer having a pH of 4 to 7 in an amount of 0.01 mol/liter or more.

11. The dampening composition for lithographic printing according to claim 1, wherein the composition further comprises at least one of organic phosphonic acid compounds and phosphoric acid.
